(19) United States
(12) Patent Application Publication
(10) Pub. No.: US 2026/0361271 A1
(43) Pub. Date: Nov. 12, 2026

(54) MIXER AND TEMPERATURE COMPENSATION METHOD THEREOF

(71) Applicant: Realtek Semiconductor Corporation, Hsinchu (TW)

(72) Inventors: Kuan-Hao TSENG, Hsinchu (TW); Sie-Siou JHANG JIAN, Hsinchu (TW); Po-Chih WANG, Hsinchu (TW)

(21) Appl. No.: 19/330,789

(22) Filed: Sep. 16, 2025

(30) Foreign Application Priority Data
May 9, 2025 (TW) 114117622

(51) Int. Cl. H03D 7/14

(52) U.S. Cl. CPC H03D 7/145; H03D 2200/0043; H03D 2200/009; H03D 2200/0098

(57) ABSTRACT

A mixer includes a switching circuit, a first transistor, a second transistor, a bias circuit and a compensation current source. The first transistor has a first terminal coupled to a first node of the switching circuit and a second terminal coupled to a ground terminal. The second transistor has a first terminal coupled to a second node of the switching circuit and a second terminal coupled to the ground terminal. The bias circuit adjusts a first conductance value of the first transistor and a second conductance value of the second transistor by a bias current. The compensation current source delivers a compensation current to the first transistor and the second transistor respectively according to an internal resistance of the bias circuit. The compensation current adjusts the first conductance value and the second conductance value, these values are not affected by an operating temperature of the mixer.

### CROSS-REFERENCE TO RELATED APPLICATION

This application claims priority to Taiwan Application Serial Number 114117622, filed May 9, 2025, which is herein incorporated by reference in its entirety.

### BACKGROUND

### Field of Invention

This disclosure relates to a mixer and temperature compensation method thereof, and in particular to the mixer involving a local oscillator leakage calibration and the temperature compensation method.

### Description of Related Art

In the field of wireless communications, analog circuits on a signal output path may have DC offsets, and these DC offsets may cause signal components that do not belong to the transmission signal to appear within the signal frequency band after being upconverted by the mixer. This phenomenon can be called local oscillation leakage (LO leakage). In order to solve the problem of local oscillation leakage, various calibration mechanisms have been proposed in the relevant technology.

However, the characteristics of the components in the mixers usually vary when the temperature changes. When the operating temperature of the calibrated mixer changes, the relevant values of the local oscillation leakage may also change accordingly, and the mixer needs to be recalibrated. When the operating temperature continues to change, the mixer must be constantly recalibrated.

How to make the mixer no longer need to be recalibrated due to changes in the operating temperature of the circuit after the local oscillation leakage calibration of the output signal is an important issue that technicians in this field must deal with.

### SUMMARY

The present disclosure provides a mixer. The mixer comprises a switching circuit, a first transistor, a second transistor, a bias circuit and a compensation current source. The first transistor comprises a first terminal coupled to a first node of the switching circuit, a control terminal, and a second terminal coupled to a ground terminal. The second transistor comprises a first terminal coupled to a second node of the switching circuit, a control terminal, and a second terminal coupled to the ground terminal. The bias circuit is coupled to the control terminal of the first transistor and the control terminal of the second transistor, and the bias circuit is configured to adjust a first conductance value of the first transistor and a second conductance value of the second transistor using a bias current. The compensation current source is coupled to the first terminal of the first transistor and the first terminal of the second transistor, and the compensation current source is configured to respectively deliver a compensation current to the first transistor and the second transistor according to an internal resistance of the bias circuit. The compensation current is configured to further adjust the first conductance value and the second conductance value such that the first conductance value and the second conductance value are not affected by an operating temperature of the mixer.

The present disclosure provides another mixer. The mixer comprises a switching circuit, a first transistor, a second transistor, a first bias circuit, a second bias circuit, a first compensation current source and a second compensation current source. The first transistor comprises a first terminal coupled to a first node of the switching circuit, a control terminal, and a second terminal coupled to a ground terminal. The second transistor comprises a first terminal coupled to a second node of the switching circuit, a control terminal, and a second terminal coupled to the ground terminal. The first bias circuit is coupled to the control terminal of the first transistor, the first bias circuit is configured to adjust a first conductance value of the first transistor using a first bias current. The second bias circuit is coupled to the control terminal of the second transistor, the second bias circuit is configured to adjust a second conductance value of the second transistor using a second bias current. The first compensation current source is coupled to the first terminal of the first transistor, and the first compensation current source is configured to deliver a first compensation current to the first transistor according to a first internal resistance of the first bias circuit. The second compensation current source is coupled to the first terminal of the second transistor, and the second compensation current source is configured to deliver a second compensation current to the second transistor according to a second internal resistance of the second bias circuit. The first compensation current is configured to further adjust the first conductance value such that the first conductance value is not affected by an operating temperature of the mixer. The second compensation current is configured to further adjust the second conductance value such that the second conductance value is not affected by the operating temperature. The first internal resistance is different from the second internal resistance.

The present disclosure provides a temperature compensation method, applicable to a mixer. The mixer comprises a switching circuit, a first transistor, and a second transistor. The temperature compensation method comprising: generating a bias circuit by a bias current; adjusting a first conductance value of the first transistor and a second conductance value of the second transistor according to the bias current; respectively delivering a compensation current to the first transistor and the second transistor by a compensation current source, wherein the compensation current is set according to an internal resistance of the bias circuit; and utilizing the compensation current to further adjust the first conductance value and the second conductance value, such that the first conductance value and the second conductance value remain substantially unaffected by variations in the operating temperature of the mixer.

According to the embodiments of the present disclosure, through the bias current provided by the bias circuit and the compensation current provided by the compensation current source, the conductance value of the transistor in the mixer may not be affected by temperature changes. Therefore, after the mixer has calibrated the local oscillation leakage of the output signal, the mixer does not need to be recalibrated due to changes in the operating temperature of the circuit.

### BRIEF DESCRIPTION OF THE DRAWINGS

FIG. 1 is a schematic diagram of a mixer according to an embodiment of the present disclosure.

FIG. 2 is a schematic diagram of the bias circuit according to the embodiment of FIG. 1.

FIG. 3 is a schematic diagram of the compensation current source according to the embodiment of FIG. 1.

FIG. 4A is schematic diagram of the conductance value of the transistor according to an embodiment of the present disclosure.

FIG. 4B is schematic diagram of the bias current according to the embodiment of embodiment of FIG. 2.

FIG. 4C is schematic diagram of the conductance value of the transistor according to the embodiment of embodiment of FIG. 1.

FIG. 5 is a schematic diagram of a mixer according to an embodiment of the present disclosure.

FIG. 6 is a flow chart of temperature compensation method according to an embodiment of the present disclosure.

### DETAILED DESCRIPTION

The embodiments are described in detail below with reference to the appended drawings to better understand the aspects of the present disclosure. However, the provided embodiments are not intended to limit the scope of the disclosure, and the description of the structural operation is not intended to limit the order in which they are performed. Any device that has been recombined by components and produces an equivalent function is within the scope covered by the disclosure.

The terms used in the entire specification and the scope of the patent application, unless otherwise specified, generally have the ordinary meaning of each term used in the field, the content disclosed herein, and the particular content.

The terms “coupled” or “connected” as used herein may mean that two or more elements are directly in physical or electrical contact, or are indirectly in physical or electrical contact with each other. It can also mean that two or more elements interact with each other.

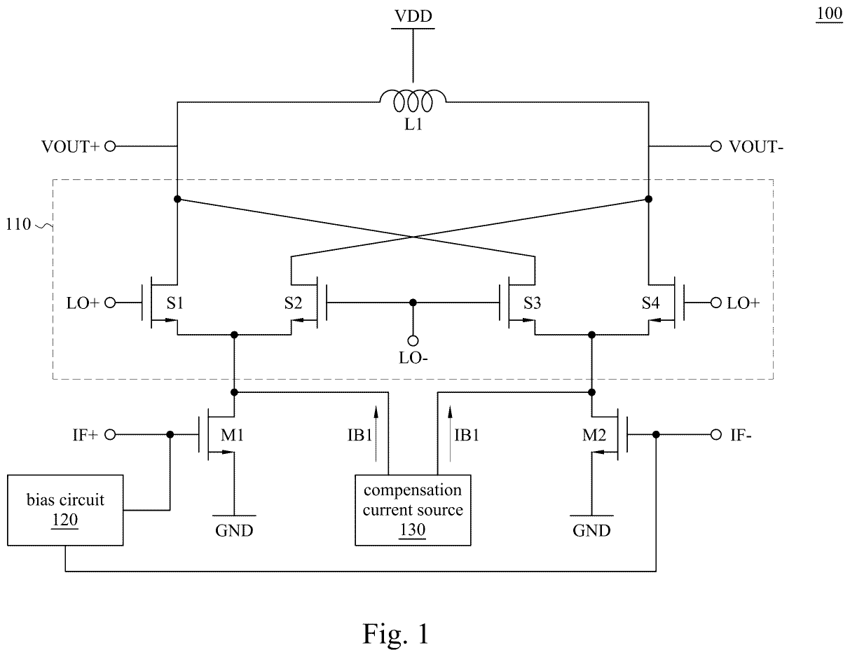

Referring to FIG. 1, FIG. 1 is a schematic diagram of a t mixer 100 according to an embodiment of the present disclosure.

The mixer 100 can be widely configured to convert an input signal from a certain frequency range to another frequency range for transmission or further signal processing. In the most common application of the mixer 100, two pairs of input signals (for example, an input signal pair and a local oscillator signal pair) can be input to the mixer 100, and the mixer 100 generates a mixed signal pair with a new frequency according to the frequency sum or frequency difference of the two pairs of input signals.

In this embodiment, the mixer 100 may be a combination circuit of a Gilbert cell mixer, a bias circuit, and a compensation current source. When the mixer 100 generates an output signal pair, a local oscillation leakage is simultaneously generated in the output signal pair. After the mixer 100 calibrates the local oscillation leakage of the output signal, the mixer 100 may perform temperature compensation through the bias circuit and the compensation current source, so that the mixer 100 does not need to repeatedly calibrate the local oscillation leakage in response to the temperature changing.

The mixer 100 comprises a switching circuit 110, a bias circuit 120, a compensation current source 130, a transistor M1, and a transistor M2. The mixer 100 may further comprise an inductor L1 for receiving an operating voltage VDD.

The first terminal (drain terminal) of the transistor M1 is coupled to the first node of switching circuit 110, the control terminal (gate terminal) of the transistor M1 receives an input signal IF+, and the second terminal (source terminal) of the transistor M1 is coupled to a ground terminal GND. The first terminal (drain terminal) of the transistor M2 is coupled to the second node of switching circuit 110, the control terminal (gate terminal) of the transistor M2 receives an input signal IF−, and the second terminal (source terminal) of the transistor M2 is coupled to the ground terminal GND. The transistors M1 and M2 may be field-effect transistors or bipolar transistors.

Transistors M1 and M2 can be configured to convert an input signal pair into a current. The switching circuit 110 is coupled to the inductor L1, and the switching circuit 110 may modulate the input signal pair which has converted into current through a local oscillator signal pair, thereby generating a mixed signal pair. The local oscillator signal pair may be local oscillator signals LO+ and LO−, the input signal pair may be input signals IF+ and IF−, and the mixed signal pair may be output signals VOUT+ and VOUT−.

The bias circuit 120 may be coupled to the control terminal of the transistor M1 and the control terminal of the transistor M2 simultaneously. A bias current may be set in the bias circuit 120. Through the bias current, the bias circuit 120 may set a bias and transmit the bias to the control terminal of the transistor M1 and the control terminal of the transistor M2 to adjust the conductance value of the transistor M1 and the transistor M2 respectively.

When the operating temperature of the mixer 100 changes, through the bias current set by the bias circuit 120, it can make the conductance values of the transistors M1 and M2 not change because of the effect of the electron mobility of the transistors or the threshold voltage of the transistors.

The compensation current source 130 is coupled to the first terminal of the transistor M1 and the first terminal of the transistor M2 respectively. The compensation current source 130 may transmit a compensation current IB1 to the transistor M1 and the transistor M2 respectively according to an internal resistance of the bias circuit 120 to further adjust the conductance value of the transistor M1 and the transistor M2.

When the operating temperature of the mixer 100 changes, the internal resistance of the bias circuit 120 may also be affected and change. At the same time, the magnitude of the compensation current IB1 output by the compensation current source 130 may also change with the operating temperature. The compensation current output by the compensation current source 130 helps to offset the influence of the internal resistance of the bias circuit 120 changing with the temperature, and the compensation current is further configured to ensure that the conductance value of the transistors M1 and M2 may not change due to the influence of the internal resistance of the bias circuit 120 when the temperature changes.

In one embodiment, a drain current of the transistor M1 is equal to the bias current of the bias circuit 120 plus the compensation current IB1. The drain current of the transistor M2 may also be equal to the bias current of the bias circuit 120 plus the compensation current IB1.

Based on the bias current set by the bias circuit 120 and the compensation current IB1 provided by the compensation current source 130 (the magnitude of the compensation current IB1 varies with the temperature), the conductance values of the transistors M1 and M2 may not change due to the change of the operating temperature of the mixer 100. Therefore, after the mixer 100 calibrates the local oscillation leakage of the output signal, the mixer 100 does not need to be recalibrated due to the change in the operating temperature.

In addition, in this embodiment, the switching circuit 110 comprises transistors S1, S2, S3, and S4.

The first terminal of transistor S1 is coupled to a node for providing an output signal VOUT+, the second terminal of transistor S1 is coupled to the first terminal of the transistor M1, and the control terminal of transistor S1 can receive the local oscillator signal LO+.

The first terminal of transistor S2 is coupled to the first terminal of transistor S4. The second terminal of transistor S2 is coupled to the first terminal of the transistor M1. The control terminal of transistor S2 can receive the local oscillator signal LO−.

The first terminal of transistor S3 is coupled to the first terminal of transistor S1, the second terminal of transistor S3 is coupled to the first terminal of the transistor M2, and the control terminal of transistor S3 can receive the local oscillator signal LO−.

The first terminal of transistor S4 is coupled to a node for providing an output signal VOUT−, the second terminal of transistor S4 is coupled to the first terminal of the transistor M2, and the control terminal of transistor S4 can receive the local oscillator signal LO+.

Transistors S1, S2, S3, and S4 can mix the input signal IF+, IF− with the local oscillator signal LO+, LO− to generate output voltages VOUT+, VOUT−.

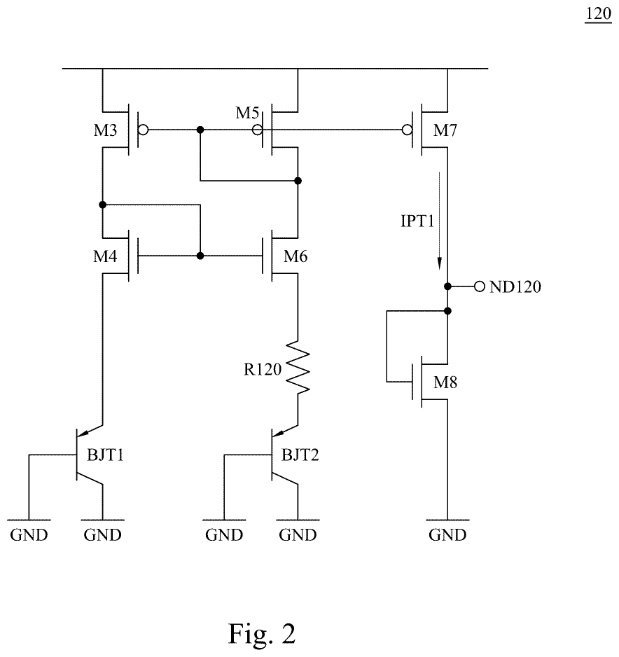

Referring to FIGS. 1 and 2, FIG. 2 is a schematic diagram of the bias circuit 120 according to the embodiment of FIG. 1. In FIG. 2, the bias circuit 120 may be a proportional to absolute temperature circuit (PTAT circuit), that is, the bias current IPT1 generated by the bias circuit 120 and the bias applied to the control terminal of the transistor M1 may increase as the temperature increases.

The bias circuit 120 comprises transistors M3, M4, M5, M6, M7, M8, BJT1, BJT2, and a resistance R120. The transistors M3, M5, and M7 may be P-type field-effect transistors. The transistors M4, M6, and M8 may be N-type field effect transistors. The transistors BJT1 and BJT2 may be bipolar transistors.

The first terminal of the transistor M3 receives the operating voltage VDD, the control terminal of the transistor M3 is coupled to the control terminal of the transistor M5 and the second terminal of the transistor M5, and the second terminal of the transistor M3 is coupled to the first terminal of the transistor M4 and the control terminal of the transistor M4. The second terminal of the transistor M4 is coupled to the first terminal of the transistor BJT1. The first terminal of the transistor M5 receives the operating voltage VDD. The first terminal of the transistor M6 is coupled to the second terminal of the transistor M5, and the control terminal of the transistor M6 is coupled to the control terminal of the fourth transistor. The resistor R120 is disposed between the second terminal of the transistor M6 and the first terminal of the transistor BJT2.

The first terminal of the transistor M7 receives the operating voltage VDD, the control terminal of the transistor M7 is coupled to the control terminal of the transistor M3, and the second terminal of the transistor M7 is coupled to a node ND120, the first terminal of the transistor M8, and the control terminal of the transistor M8. In conjunction with FIG. 1, the node ND120 of the bias circuit 120 in FIG. 2 is the same as the node of the bias circuit 120 coupled to the control terminals of transistors M1 and M2 in FIG. 1. In other words, the second terminal of the transistor M7 can be coupled with the control terminal of the transistor M1 and the control terminal of the transistor M2.

The second terminal of the transistor M8 is coupled to the ground terminal GND. The control terminal and the second terminal of the transistor BJT1 are both coupled to the ground terminal GND. The control terminal and the second terminal of the transistor BJT2 are both coupled to the ground terminal GND.

It is worth mentioning that the internal resistance of resistor R120 is the internal resistance of bias circuit 120 mentioned above.

The bias current IPT1 may be set in the bias circuit 120. The bias current IPT1 may be the absolute temperature current generated by the PTAT circuit. The bias current IPT1 is generated according to the following formula 1:

$$IPT = Vt \frac{ln ( n )}{R} \qquad [ formula 1 ]$$

Wherein “IPT” represents the current value of bias current IPT1, “Vt” represents a threshold voltage of a transistor (e.g., the transistor M8), “R” represents the internal resistance of resistance R120, and “n” represents a ratio of the bipolar transistor BJT2 to the bipolar transistor BJT1.

The bias circuit 120 can provide a bias to the node ND120 through the bias current IPT1. The bias can be transmitted to the control terminal (gate) of the transistor M1 through the node ND120, so that the drain current of the transistor M1 is equal to the current value of the bias current IPT1. Therefore, the conductance value of the transistor M1 can be adjusted, as described in the following formula 2:

$$IPT = {I}_{MD 1} \qquad [ formula 2 ]$$

$${I}_{MD 1} = {V}_{t} \frac{ln ( n )}{R} = \frac{1}{2} {μ}_{n} {{C}_{ox} ( {V}_{gs} - {V}_{t} )}^{2}$$

$${V}_{gs} = \frac{2 {V}_{t} \pm \sqrt{\frac{8 {V}_{t} \frac{ln ( n )}{R}}{{μ}_{n} {C}_{ox}}}}{2}$$

$$When$$

$${V}_{t} = \frac{2 \frac{ln ( n )}{R}}{{μ}_{n} {C}_{ox}} , {V}_{gs} = 2 {V}_{t}$$

$${g}_{m 1} = {μ}_{n} {C}_{ox} \frac{W}{L} ( {V}_{gs} - {V}_{t} )$$

$${g}_{m 1} = 2 \frac{ln ( n )}{R} \frac{W}{L}$$

Wherein “I_{MD1}” represents the drain current of the transistor M1, “μₙ” represents the electron mobility of the transistor M1, “Cₒₓ” represents the oxide capacitance per unit area of the transistor M1, “gₘ₁” represents the conductance value of the transistor M1, “W/L” represents the scaling ratio of the transistor M1.

When the operating temperature of the mixer 100 changes, the electron mobility (i.e., “μₙ” in the formula 2) or the threshold voltage (i.e., “Vₜ” in the formula 2) may change. Through the bias current IPT1, the conductance value of the transistor M1 may be kept constant when the temperature changes and may not be affected by the electron mobility or the threshold voltage. In this circumstance, when the temperature changes, the conductance value of the transistor M1 may only be affected by the internal resistance of the resistance R120 (i.e., “R” in the formula 2) that changes with the temperature.

Incidentally, in this embodiment, the bias may also be transmitted to the control terminal (gate) of the transistor M2 through the node ND120, so that the drain current of the transistor M2 is equal to the current value of the bias current IPT1. Therefore, the conductance value of the transistor M2 can be adjusted. Through the bias current IPT1, the conductance value of the transistor M2 may also not be affected by the electron mobility or the threshold voltage when the temperature changes. In this circumstance, the conductance value of the transistor M2 is also only affected by the internal resistance of the resistance R120.

To prevent the conductance values of the transistors M1 and M2 from being affected by the internal resistance of the resistance R120 when the temperature changes, the compensation current source 130 may deliver the compensation current IB1 to the first terminals of the transistors M1 and M2 respectively.

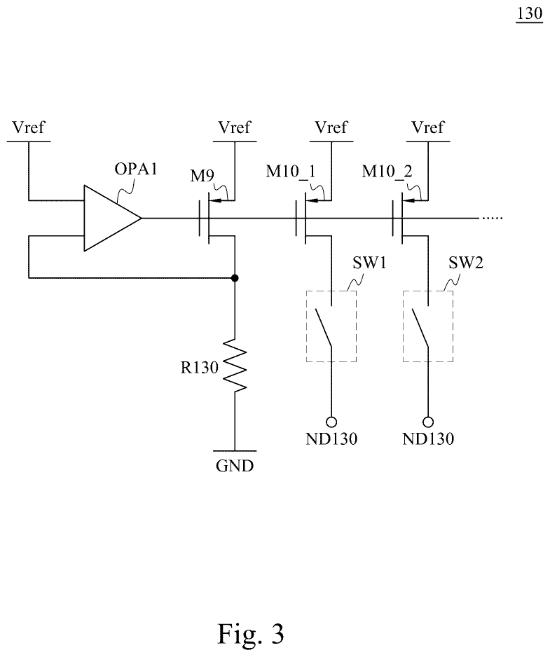

Referring to FIGS. 1 and 3, FIG. 3 is a schematic diagram of the compensation current source 130 according to the embodiment of FIG. 1.

The compensation current source 130 comprises a resistance R130, an operational amplifier OPA1, a transistor M9, at least one tenth transistor (e.g., a transistor 10_1 and a transistor 10_2 in FIG. 3), and at least one switch corresponding to the at least one tenth transistor (e.g., a switch SW1 and a switch SW2 in FIG. 3).

The first input node of the operational amplifier OPA1 receives a reference voltage Vref. The resistor R130 is disposed between the second input node of the operational amplifier OPA1 and the ground terminal GND. The output node of the operational amplifier OPA1 is coupled to the control terminal of the transistor M9 and the control terminal of the at least one tenth transistor. The first terminal of the transistor M9 receives the reference voltage Vref.

The first terminal of the at least one tenth transistor (transistor 10_1, transistor 10_2) receives the reference voltage Vref, and the second terminal of the at least one tenth transistor is coupled to the first terminal of the at least one switch (the switch SW1, switch SW2). The second terminal of the at least one switch is coupled to a node ND130. In combination with FIG. 1, the node ND130 of the compensation current source 130 in FIG. 3 can be coupled to the first terminal of the transistor M1 and the first terminal of the transistor M2 coupled to the compensation current source 130 in FIG. 1. In other words, the second terminal of one of the at least one switch (e.g., the switch SW1) can be coupled to the first terminal of the transistor M1, and the second terminal of the other of the at least one switch (e.g., switch SW2) can be coupled to the first terminal of the transistor M2.

It is worth mentioning that the internal resistance of the resistance R130 is equal to the internal resistance of the resistance R120 in bias circuit 120.

The compensation current source 130 can set the compensation current IB1, and the compensation current IB1 is generated according to the following formula 3:

$$IB 1 = \frac{Vref}{R} \qquad [ formula 3 ]$$

Wherein “IB1” represents is the current value of the compensation current IB1 transmitted to the transistors M1 and M2 by the compensation current source 130, “Vref” represents the voltage level of the reference voltage Vref, “R” represents the internal resistance of the resistance R130. Moreover, the resistance value of the resistance R120 of the bias circuit 120 is equal to the resistance value of the resistance R130 of the compensation current source 130.

When the operating temperature of the mixer 100 changes, since the compensation current IB1 is transmitted to the first terminals of the transistors M1 and M2, the conductance values of the transistors M1 and M2 remain substantially unaffected by the change of the resistance R120 of the bias circuit 120.

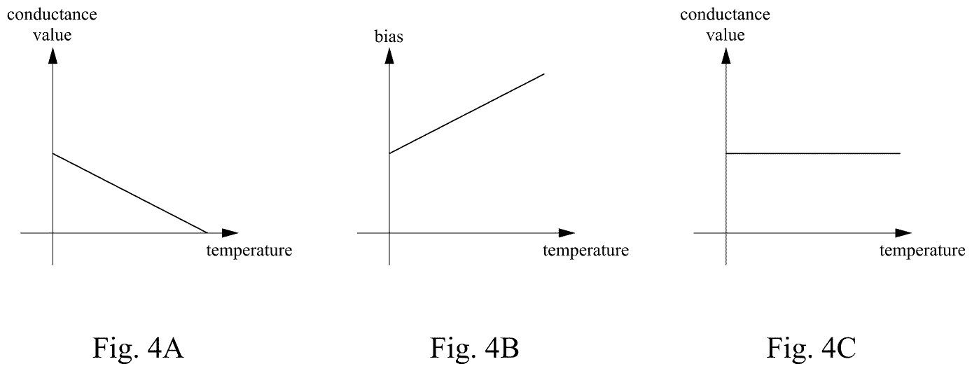

Referring to FIGS. 1, 2, 4A, 4B, and 4C simultaneously. FIG. 4A is schematic diagram of the conductance value of the transistor M1 according to an embodiment of the present disclosure. FIG. 4B is schematic diagram of the bias current IPT1 according to the embodiment of embodiment of FIG. 2. FIG. 4C is schematic diagram of the conductance value of the transistor M1 according to the embodiment of embodiment of FIG. 1.

The conductance value of the transistor M1 exhibits a negative temperature coefficient. In the embodiment of FIG. 4A, since the transistor M1 does not receive the bias provided by bias circuit 120 or the compensation current IB1 provided by compensation current source 130, the conductance value of the transistor M1 decreases as the temperature increases.

In the embodiment of FIG. 4B, since the bias circuit 120 is a PTAT circuit, the bias current IPT1 generated by the bias circuit 120 increases as the temperature increases.

In the embodiment of FIG. 4C, since the transistor M1 of the mixer 100 receives the bias based on the bias current IPT1 provided by the bias circuit 120 and the compensation current IB1 of the compensation current source 130, the conductance value of the transistor M1 remains unchanged when the temperature increases.

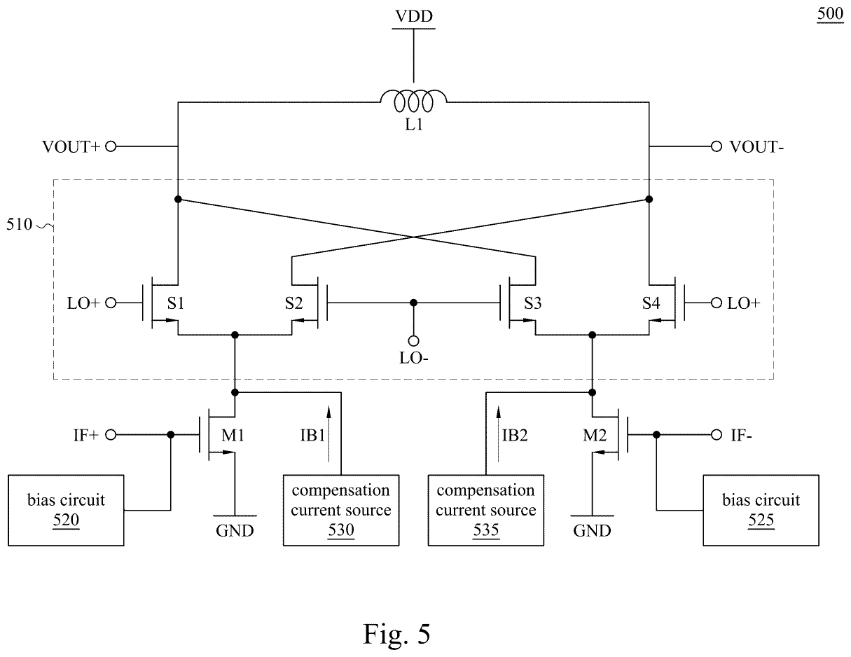

Referring to FIGS. 1 and 5 simultaneously, FIG. 5 is a schematic diagram of a mixer 500 according to an embodiment of the present disclosure. In the embodiment of FIG. 5, the mixer 500 comprises a switching circuit 510, a bias circuit 520, a bias circuit 525, a compensation current source 530, a compensation current source 535, the transistor M1, and the transistor M2.

The circuit details of the switching circuit 510 are the same as the circuit details of the switching circuit 110 in FIG. 1. The device characteristics of the transistor M1 and the transistor M2 in FIG. 5 are the same as the device characteristics of the transistor M1 and the transistor M2 in FIG. 1.

The bias circuit 520 may be coupled to the control terminal of the transistor M1. A bias current may be set in the bias circuit 520. Through the bias current, the bias circuit 520 may set a bias at the control terminal of the transistor M1 to adjust the conductance value of the transistor M1.

The bias circuit 525 may be coupled to the control terminal of the transistor M2. Another bias current may be set in the bias circuit 525. Through the other bias current, the bias circuit 525 may set another bias at the control terminal of the transistor M2 to adjust the conductance value of the transistor M2.

The circuit details of the bias circuit 520 and the bias circuit 525 in FIG. 5 may refer to the bias circuit 120 in FIG. 1. It should be noticed that the internal resistance of the bias circuit 520 may be different from the internal resistance of the bias circuit 525.

The compensation current source 530 delivers a compensation current IB1 to the first terminal of the transistor M1 according to the internal resistance of the bias circuit 520, and the compensation current source 535 delivers a compensation current IB2 to the first terminal of the transistor M2 according to the internal resistance of the bias circuit 525. Since the internal resistance of the bias circuit 520 may be different from the internal resistance of the bias circuit 525, the compensation current IB1 may be different from the compensation current IB2.

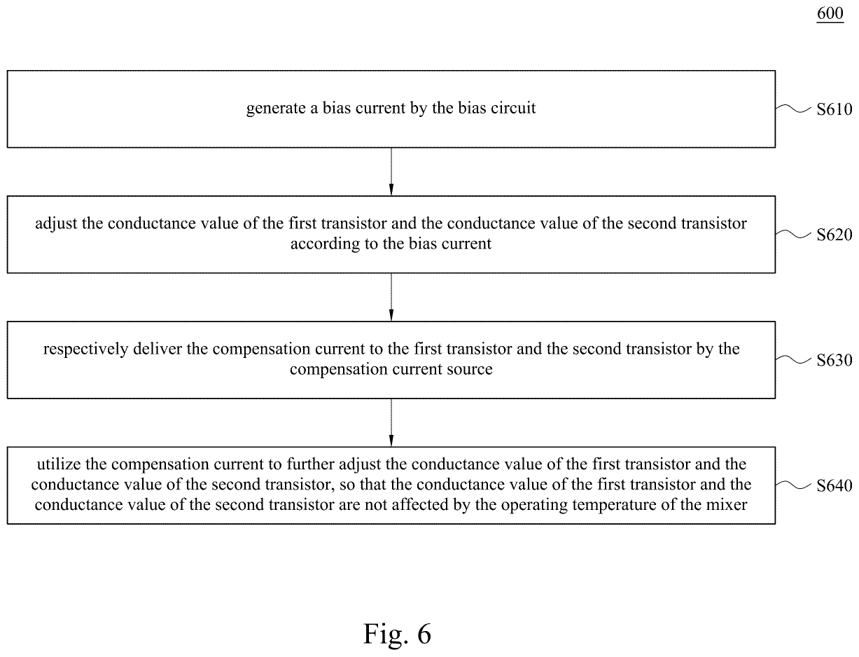

Referring to FIG. 6, FIG. 6 is a flow chart of temperature compensation method 600 according to an embodiment of the present disclosure. The temperature compensation method 600 is configured to perform temperature compensation on the mixer 100 so that the conductance value of the transistor M1 and the conductance value of the transistor M2 in the mixer 100 do not change when the temperature changes.

In step S610, the mixer 100 may generate a bias current IPT1 by the bias circuit 120.

In step S620, the mixer 100 may adjust the conductance value of the first transistor (e.g., the transistor M1 in FIG. 1) and the conductance value of the second transistor (e.g., the transistor M2 in FIG. 1) according to the bias current IPT1.

In step S630, the mixer 100 may respectively deliver the compensation current IB1 to the first transistor and the second transistor by the compensation current source 130.

In step S640, the mixer 100 may utilize the compensation current IB1 to further adjust the conductance value of the first transistor and the conductance value of the second transistor, so that the conductance value of the first transistor and the conductance value of the second transistor are not affected by the operating temperature of the mixer 100.

In summary, the bias current provided by the bias circuit and the compensation current provided by the compensation current source of the present disclosure can prevent the conductance value of the transistor in the mixer from being affected by the temperature changes. Therefore, after the mixer 100 calibrates the local oscillation leakage of the mixed signal pair (i.e., output signal Vout+, Vout−), it does not need to be recalibrated when the temperature changes.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the invention. In view of the foregoing, it is intended that the present invention cover modifications and variations of this invention provided they fall within the scope of the following claims.

What is claimed is:

1. A mixer, comprising:
a switching circuit;
a first transistor, comprising a first terminal coupled to a first node of the switching circuit, a control terminal, and a second terminal coupled to a ground terminal;
a second transistor, comprising a first terminal coupled to a second node of the switching circuit, a control terminal, and a second terminal coupled to the ground terminal;
a bias circuit, coupled to the control terminal of the first transistor and the control terminal of the second transistor, the bias circuit is configured to adjust a first conductance value of the first transistor and a second conductance value of the second transistor by using a bias current; and
a compensation current source, coupled to the first terminal of the first transistor and the first terminal of the second transistor, the compensation current source is configured to respectively deliver a compensation current to the first transistor and the second transistor according to an internal resistance of the bias circuit,
wherein the compensation current is configured to further adjust the first conductance value and the second conductance value such that the first conductance value and the second conductance value are not affected by an operating temperature of the mixer.

2. The mixer of claim 1, wherein the bias circuit sets a bias through the bias current and transmits the bias to the control terminal of the first transistor and the control terminal of the second transistor.

3. The mixer of claim 1, wherein the bias circuit is a proportional to absolute temperature circuit, and the bias generated by the proportional to absolute temperature circuit increases as the operating temperature increases.

4. The mixer of claim 2, wherein the bias circuit comprises:
a third transistor, comprising a first terminal receiving an operating voltage, a control terminal, and a second terminal;
a fourth transistor, comprising a first terminal and a control terminal coupled to the second terminal of the third transistor, and a second terminal;
a fifth transistor, comprising a first terminal receiving the operating voltage, a control terminal coupled to the control terminal of the third transistor, and a second terminal;
a sixth transistor, comprising a first terminal coupled to the second terminal of the fifth transistor, a control terminal coupled to the control terminal of the fourth transistor, and a second terminal;
a seventh transistor, comprising a first terminal receiving the operating voltage, a control terminal coupled to the control terminal of the third transistor, and a second terminal coupled to the control terminal of the first transistor;
an eighth transistor, comprising a first terminal and a control terminal coupled to the second terminal of the seventh transistor, and a second terminal coupled to the ground terminal;
a first bipolar transistor, comprising a first terminal coupled to the second terminal of the fourth transistor, and a control terminal and a second terminal coupled to the ground terminal;
a second bipolar transistor, comprising a first terminal, a control terminal coupled to the ground terminal, and a second terminal; and
a first resistance, comprising a first terminal coupled to the second terminal of the sixth transistor, and a second terminal coupled to the second bipolar transistor.

5. The mixer of claim 4, wherein the internal resistance of the bias circuit is a resistance value of the first resistance.

6. The mixer of claim 5, wherein the bias current is generated according to a formula below:
$$IPT = Vt \frac{ln ( n )}{R}$$
wherein “IPT” represents the bias current, “Vt” represents a threshold voltage, “R” represents the internal resistance, and “n” represents a ratio of the second bipolar transistor to the first bipolar transistor.

7. The mixer of claim 1, wherein the compensation current source comprises:
a second resistance;
an operational amplifier, comprising a first input node receiving a reference voltage, a second input node coupled to the second resistance, and an output node;
a ninth transistor, comprising a first terminal receiving the reference voltage, a control terminal coupled to the output node of the operational amplifier, and a second terminal coupled to the second resistance;
at least one tenth transistor, comprising a first terminal receiving the reference voltage, a control terminal coupled to the output node of the operational amplifier, and a second terminal; and
at least one switch, comprising a first terminal coupled to the second terminal of the at least one tenth transistor, and a second terminal coupled to the first terminal of the first transistor.

8. The mixer of claim 7, wherein a resistance value of the second resistance of the compensation current source is equal to the internal resistance of the bias circuit.

9. The mixer of claim 1, wherein the first transistor and the second transistor are configured to convert an input signal pair into a current, and the switching circuit modulates the current through an oscillating signal pair to generate a mixed signal pair.

10. The mixer of claim 9, wherein the switching circuit comprises:
a first switching transistor, comprising a first terminal, a second terminal coupled to the first terminal of the first transistor, and a control terminal receiving a first local oscillator signal of the oscillating signal pair;
a second switching transistor, comprising a first terminal, a second terminal coupled to the first terminal of the first transistor, and a control terminal receiving a second local oscillator signal of the oscillating signal pair;
a third switching transistor, comprising a first terminal coupled to the first terminal of the first switching transistor, a second terminal coupled to the first terminal of the second transistor, and a control terminal receiving the second local oscillator signal; and
a fourth switching transistor, comprising a first terminal coupled to the first terminal of the second switching transistor, a second terminal coupled to the first terminal of the second transistor, and a control terminal receiving the first local oscillator signal.

11. A mixer, comprising:
a switching circuit;
a first transistor, comprising a first terminal coupled to a first node of the switching circuit, a control terminal, and a second terminal coupled to a ground terminal;
a second transistor, comprising a first terminal coupled to a second node of the switching circuit, a control terminal, and a second terminal coupled to the ground terminal;
a first bias circuit, coupled to the control terminal of the first transistor, the first bias circuit is configured to adjust a first conductance value of the first transistor using a first bias current;
a second bias circuit, coupled to the control terminal of the second transistor, the second bias circuit is configured to adjust a second conductance value of the second transistor using a second bias current;
a first compensation current source, coupled to the first terminal of the first transistor, the first compensation current source is configured to deliver a first compensation current to the first transistor according to a first internal resistance of the first bias circuit; and
a second compensation current source, coupled to the first terminal of the second transistor, the second compensation current source is configured to deliver a second compensation current to the second transistor according to a second internal resistance of the second bias circuit,
wherein the first compensation current is configured to further adjust the first conductance value such that the first conductance value is not affected by an operating temperature of the mixer,
wherein the second compensation current is configured to further adjust the second conductance value such that the second conductance value is not affected by the operating temperature,
wherein the first internal resistance is different from the second internal resistance.

12. The mixer of claim 11, wherein
the first bias circuit sets a first bias through the first bias current and transmits the first bias to the control terminal of the first transistor,
the second bias circuit sets a second bias through the second bias current and transmits the second bias to the control terminal of the second transistor.

13. The mixer of claim 12, wherein the first bias circuit and the second bias circuit are both proportional to absolute temperature circuits, and the first bias and the second bias increase as the operating temperature increases.

14. The mixer of claim 11, wherein the first bias current is generated according to a formula below:
$$IPT 1 = Vt 1 \frac{ln ( n 1 )}{R 1}$$
wherein “IPT1” represents the first bias current, “Vt1” represents a first threshold voltage, “R1” represents the first internal resistance, and “n1” represents a ratio of a second bipolar transistor to a first bipolar transistor in the first bias circuit,
wherein the second bias current is generated according to a formula below:
$$IPT 2 = Vt 2 \frac{ln ( n 2 )}{R 2}$$
wherein “IPT2” represents the second bias current, “Vt2” represents a second threshold voltage, “R2” represents the second internal resistance, and “n2” represents a ratio of a third bipolar transistor to a fourth bipolar transistor in the second bias circuit.

15. The mixer of claim 11, wherein the first transistor and the second transistor are configured to convert an input signal pair into a current, and the switching circuit modulates the current through an oscillating signal pair to generate a mixed signal pair.

16. A temperature compensation method, applicable to a mixer, wherein the mixer comprises a switching circuit, a first transistor, and a second transistor, and the temperature compensation method comprising:
generating a bias current by a bias circuit;
adjusting a first conductance value of the first transistor and a second conductance value of the second transistor according to the bias current;
respectively delivering a compensation current to the first transistor and the second transistor by a compensation current source, wherein the compensation current is set according to an internal resistance of the bias circuit; and
utilizing the compensation current to further adjust the first conductance value and the second conductance value, so that the first conductance value and the second conductance value are not affected by an operating temperature of the mixer.

17. The temperature compensation method of claim 16, further comprising:
setting a bias through the bias current, and transmitting the bias to a control terminal of the first transistor and a control terminal of the second transistor to adjust the first conductance value and the second conductance value.

18. The temperature compensation method of claim 17, wherein the bias circuit is a proportional to absolute temperature circuit, and the bias generated by the proportional to absolute temperature circuit increases as the operating temperature increases.

19. The temperature compensation method of claim 16, wherein the bias circuit comprises a first bipolar transistor and a second bipolar transistor, and wherein the bias current is generated according to a formula below:
$$IPT = Vt \frac{ln ( n )}{R}$$
wherein “IPT” represents the bias current, “Vt” represents a threshold voltage, “R” represents the internal resistance, and “n” represents a ratio of the second bipolar transistor to the first bipolar transistor.

20. The temperature compensation method of claim 16, wherein the first transistor and the second transistor are configured to convert an input signal pair into a current, and the switching circuit modulates the current through an oscillating signal pair to generate a mixed signal pair.
